(19) United States
(12) Patent Application Publication
(10) Pub. No.: US 2017/0341346 A1
(43) Pub. Date: Nov. 30, 2017

(54) LAMINATED GLASS LUMINESCENT CONCENTRATOR

(71) Applicant: UbiQD, LLC, Los Alamos, NM (US)

(72) Inventors: Hunter McDaniel, Los Alamos, NM (US); Aaron Jackson, LOS ALAMOS, NM (US); Matthew R. Bergren, LOS ALAMOS, NM (US)

(73) Assignee: UbiQD, LLC, Los Alamos, NM (US)

(21) Appl. No.: 15/604,656

(22) Filed: May 25, 2017

Related U.S. Application Data
(60) Provisional application No. 62/341,238, filed on May 25, 2016.

(51) Int. Cl. B32B 17/10; B32B 17/08; H01L 31/055

(52) U.S. Cl. CPC B32B 17/10449; B32B 17/10036; B32B 17/10614; B32B 17/10743; B32B 17/10761; H01L 31/055; B32B 17/10871; B32B 17/10908; B32B 17/10935; B32B 17/08; B32B 17/10788; B32B 2305/72; B32B 2305/30; B32B 2264/12; B32B 2255/26; B32B 2307/422; B32B 2311/12; B32B 2311/20; B32B 2315/08; B32B 2317/18; B32B 2329/06; B32B 2331/04; B32B 2333/12; B32B 2419/00; B32B 2457/12; B32B 2605/08

(57) ABSTRACT

A laminated glass luminescent concentrator is provided which includes a solid medium having a plurality of fluorophores disposed therein. In some embodiments, the fluorophore is a low-toxicity quantum dot. In some embodiments, the fluorophore has significantly reduced self-absorption, which allows for unperturbed waveguiding of the photoluminescence over a long distance. Also disclosed are apparatuses for generating electricity from the laminated glass luminescent concentrator, and its combination with buildings and vehicles.

### CROSS-REFERENCE TO RELATED APPLICATION

This application claims the benefit of priority from U.S. provisional application No. 62/341,238, filed May 25, 2016, having the same inventor and the same title, and which is incorporated herein by referenced in its entirety.

### ACKNOWLEDGMENT OF GOVERNMENT SUPPORT

This invention was made with Government support under Contract No. 1622211 awarded by the National Science Foundation. The Government has certain rights to this invention.

### FIELD OF THE DISCLOSURE

The present disclosure relates generally to devices featuring photoluminescent materials embedded between sheets of glass, and more specifically to laminated glass luminescent concentrators containing photoluminescent materials, such as quantum dots with high quantum yield and low self-absorbance, and to systems using the same in conjunction with a photovoltaic cell for the generation of electricity.

### BACKGROUND OF THE DISCLOSURE

Luminescent concentrators (LCs) are devices which utilize luminescent materials to harvest electromagnetic radiation, typically for the purpose of generating electricity. A common set-up 101 of such a device for this purpose is depicted in FIG. 1. As seen therein, the LC 102 is utilized to collect solar radiation 103 over a relatively large area, and to concentrate it onto a relatively small area (here, the active surface of a photovoltaic cell 104). The photovoltaic cell 104 then converts the radiation into electricity to provide power 105 for end user devices. The LC 102 acts as a waveguide comprising a luminescent material which must both create and transmit the same luminescence. The waveguide is typically a polymeric material of optical quality. When sunlight or other radiation impinges on the luminescent material, the material undergoes luminescence (and most commonly, fluorescence) and emits light into the waveguide. From there, the entrapped light is directed to the photovoltaic cell 104. Since the radiation emitted by the luminescent material is typically emitted at different wavelengths than the radiation initially absorbed by the luminescent material, the solar concentrator 102 has the effect of both concentrating and modifying the spectrum of the radiation which is impingent on it.

One of the first reports of an LSC can be found in U.S. Pat. No. 4,227,939 (Zewail et al), entitled “Luminescent Solar Energy Concentrator Devices,” which was filed in 1979. This reference notes that “Snell's law dictates that a large fraction, typically 75%, of this reemission strikes the surface of the substrate with an angle of incidence greater than the critical angle, so that this fraction of the light is then trapped in the substrate by internal reflection until successive reflection carries it to the edge of the plate where it enters an absorber placed at the edge of the plate.” One of the biggest drawbacks of this approach is its reliance on a monolithic polymer slab/sheet as a structural material for a window, building, or vehicle, since polymeric materials are frequently not reliable in outdoor conditions. Moreover, the typical polymeric materials that are useful in this application are prone to abrasion. In addition to perturbing the view through a window, abrasion also impairs LC performance by introducing light scattering centers into the waveguide.

Glass is ubiquitous in modern society, and can be found in consumer electronics, facades of buildings, automobile structures, and windows. Although glass has potential as a durable LC material, it has two main drawbacks: (1) no adequate luminescent materials are currently known to the art which can survive the melting temperature/process of glass, and (2) typical float glass has poor transitivity over long distances due to metal impurities such as iron.

One important innovation in glass was the development of laminated “safety” glass. The first known patent relating to laminated glass was French Patent No. 321,651 (Le Carbon), which was filed in 1902, and which notes that coating glass objects with celluloid can render them less susceptible to cracking or breaking. However, credit for the invention of laminated glass typically goes to French chemist Edouard Benedictus, who was apparently inspired by a 1903 laboratory accident when a glass flask that had become coated with plastic did not break after being dropped. Benedictus filed French Patent No. 405,881 in 1909, and then he formed Societe du Verre Triplex, which fabricated a glass-plastic composite.

Around this same time, John Crewe Wood (England) filed U.S. 830,398, entitled “Transparent screen”, which noted that “celluloid screens soon become scratched and rendered less transparent, [whereas] my invention prevents this . . . consists in providing two sheets of glass between which cemented a sheet.” It will thus be appreciated that, while the laminate polymer interlayer adds shatter resistance to glass, glass also adds abrasion resistance to the polymer.

In 1927, the polyvinyl butyral (PVB) laminate interlayer was discovered by Matheson and Skirrow. This composite material is described in U.S. Pat. No. 1,725,362 (Matheson et al.), entitled “Vinyl ester resins and process of making same.” This material was not prone to discoloration and was resistant to penetration. Within a few years, PVB safety glass dominated the marketplace, and in 1930, the British parliament required all new cars to be equipped with laminated glass windshields. In subsequent years, laminated glass technology was further developed and improved by various organizations, including Libbey Owens-Ford Glass Company, Du Pont de Nemours, Pittsburgh Plate Glass Company, and others.

### BRIEF DESCRIPTION OF THE DRAWINGS

FIG. 1 is a schematic illustration of a typical LC wherein a fluorophore is embedded in a polymer medium. The concentrator is coupled to a photovoltaic cell for the conversion of light into electricity.

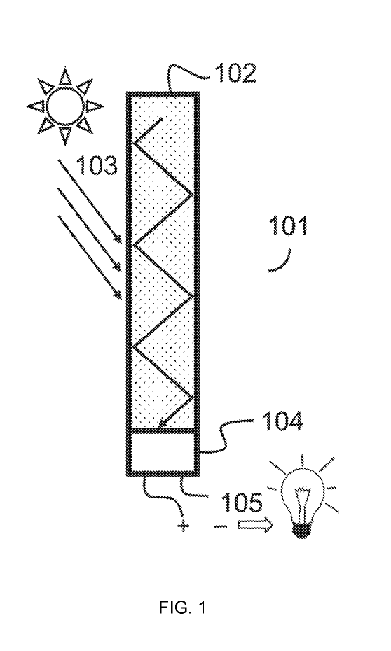

FIG. 2 is a schematic illustration of a laminated glass LC wherein a fluorophore is embedded in a medium disposed between two sheets of glass. The concentrator is coupled to a photovoltaic cell for the conversion of light into electricity. In some embodiments, the LC is partially transparent and can be used as a window.

FIG. 3 is a schematic illustration of a laminated glass LC wherein a fluorophore is embedded in a medium between two sheets of glass. The concentrator converts a spectrum and photon flux of electromagnetic radiation into a new spectrum with a higher photon flux at the edges.

FIG. 4 is a graph of a typical absorption and photoluminescence spectra for exemplary CuInSeₓS₂₋ₓ/ZnS quantum dots. These QDs have low self-absorption due to a large separation between absorption and photoluminescence. Additionally, these QDs avoid the toxic elements found in most QDs, such as cadmium, lead, or mercury.

FIG. 5 is a graph of the photoluminescence spectra arising from different sizes and compositions of quantum dots composed of CuInS₂, CuInSe₂, ZnS, ZnSe, and combinations thereof. The accessible peak emissions with these materials is 400 nm-1300 nm, and they can be made to have quantum yields up to 100%.

FIG. 6 is a schematic illustration of a laminated glass LC, wherein a plurality of quantum dots is embedded in a medium between two sheets of glass. In some embodiments, the interlayer was made by an extrusion process.

FIG. 7 is a schematic illustration of a laminated glass LC, wherein a plurality of quantum dots is embedded at the interfaces between sheets of glass and one or more interlayers.

FIG. 8 is a schematic illustration of a laminated glass LC, wherein a fluorophore is embedded in a liquid medium disposed between two vertical sheets of glass prior to curing the liquid into a solid interlayer.

FIG. 9 is a schematic illustration of a laminated glass LC, wherein a fluorophore is embedded in a liquid medium disposed between two horizontal sheets of glass prior to curing the liquid into a solid interlayer.

FIG. 10 is a schematic illustration of a laminated glass LC in combination with an insulated glass unit, a window frame and a photovoltaic.

FIG. 11 is a schematic illustration of a laminated glass LC in combination with an automobile.

FIG. 12 is a schematic illustration of a laminated glass LC in combination with a building structure.

### SUMMARY OF THE DISCLOSURE

In one aspect, an LC is provided which comprises (a) at least two sheets of glass in direct contact with at least one solid medium; and (b) a plurality of fluorophores disposed in said medium which, upon excitation with a light source, exhibit a guided luminescence in the medium.

In another aspect, an LC is provided which comprises (a) at least two sheets of glass; (b) a solid medium; and (c) a plurality of fluorophores disposed in said medium which, upon excitation with a light source, exhibit a quantum yield greater than 20%, and low self-absorption such that the photoluminescence is absorbed by less than 50% across the integrated spectrum by said fluorophores embedded in said medium over distances of 1 mm to 10 m.

In a further aspect, and in combination with a photovoltaic, the LC has the ability to convert light, for example sunlight, into electricity. In one embodiment, said light is partially absorbed by less than 50% across the integrated incident light spectrum. In other embodiments, said light is mostly absorbed, by more than 50% across the integrated incident light spectrum.

In still another aspect, an LC is provided which comprises first and second sheets of glass, and a solid medium containing a plurality of fluorophores. The solid medium is disposed between, and is in contact with, said first and second sheets of glass.

In a further aspect, a method is provided for making a luminescent concentrator. The method comprises providing first and second sheets of glass; coating a first surface of the first sheet of glass with a luminescent material, thereby forming a first coated surface, wherein said luminescent material comprises a solid medium containing a plurality of fluorophores; and assembling the first and second sheets of glass into a construct such that the first coated surface is facing the second sheet of glass.

In yet another aspect, a method is provided for making a luminescent concentrator. The method comprises providing first and second sheets of glass; and disposing a luminescent material between, and in direct contact with, said first and second sheets of glass, wherein said luminescent material comprises a medium containing a plurality of fluorophores.

### DETAILED DESCRIPTION

### 1. Background

The optical properties of LCs should meet two primary requirements. First, the LC surfaces should be capable of guiding light and should be resistant to abrasion. Abrasion can introduce scattering centers which enable light to escape from total internal reflection, thus reducing efficiency. Second, the fluorophore should have low self-absorbance. Self-absorbance of the luminescence allows light to escape from total internal reflection, thus reducing its concentration or flux at the edge.

Preferred embodiments of the compositions, systems, methodologies and devices of the present disclosure solve the foregoing problems by embedding a suitable fluorphore material between two sheets of glass (such glass is also known as laminated glass or safety glass). Furthermore, a suitable fluorophore technology is identified in quantum dots (QDs) that have a large intrinsic Stokes shift such as, for example, those composed of CuInSeₓS₂₋ₓ/ZnS (core/shell). When combined with an optically coupled photovoltaic device, the LC may generate electricity under illumination by sunlight or other suitable sources. In some embodiments, the LC may be partially transparent, and may be used as (or in) a window of a building or vehicle. Additional benefits may be realized in the safety of building or automobile occupants, since the laminated glass in the foregoing constructs may be engineered to be robust against shattering, or may be inherently resistant to shattering. In certain embodiments and applications, the LC may be fully absorptive, and may therefore provide a lower-cost alternative to large area photovoltaics (such as, for example, those used in solar farms).

The LC may be semi-transparent, and may filter visible light neutrally so as to avoid imparting unnatural color to the transmitted light. In contrast to conventional solar harvesting window concepts which utilize photovoltaic stacks that cover the entire window, LCs typically require only a very narrow strip of PV along one or more edges of the window. Conventional solar harvesting window concepts are hence intrinsically more expensive and complex than LCs, because they require coating an entire window with a complex, multi-layered PV.

LCs may have advantages in applications beyond sunlight harvesting such as, for example, but not limited to, lighting, design, security, art, and other applications where creating a new spectrum and/or higher photon flux is desirable. The same fluorophores and/or device geometries that are applicable to sunlight harvesting may be applicable to these other usages. In other cases, new fluorophores and/or new device geometries may be desirable for non-solar applications.

Photoluminescence (PL) is the emission of light (electromagnetic radiation, photons) after the absorption of light. It is one form of luminescence (light emission) and is initiated by photoexcitation (excitation by photons). Following photon excitation, various charge relaxation processes can occur in which other photons with a lower energy are re-radiated on some time scale. The energy difference between the absorbed photons and the emitted photons, also known as Stokes shift, can vary widely across materials from nearly zero to 1 eV or more.

Current LC devices typically utilize monolithic polymer slabs (containing no glass) embedded with common fluorophores such as dyes or QDs. In some cases, previous iterations of LCs have utilized a sheet of glass in their designs.

For example, U.S. 2012/0024345 (Reisfeld et al.) discloses using glass or plastic as a substrate for a dye-containing film. Specifically, paragraph [0018] of the reference provides: “The present invention provides a luminescent solar concentrator (LSC) exhibiting high efficiency, and durable fluorescence properties, comprising at least one plate having two major surfaces and a plurality of edges having solar cells attached thereto, said plate comprising a substrate selected from the group consisting of glass and plastic and being provided with a composite inorganic-organic sol-gel based film deposited on at least one major surface thereof, wherein said film is doped with at least one luminescent dye and said concentrator comprises at least three luminescent dyes of substantially different absorption ranges and wherein said film has a thickness of at least 10 μm.” The reference notes that quantum dots can be used in the concentrator (see paragraphs [0063]-[0064]). Notably, and in contrast to the disclosure of the '345 application, in preferred embodiments of the compositions, systems, methodologies and devices described herein, glass is not used as a substrate. Instead, at least two sheets of glass are laminated with an interlayer containing the fluorophore, and both of the adjacent sheets are optically coupled and utilized for waveguiding.

In some cases, previous iterations of LCs have utilized multiple sheets of glass to separate multiple fluorophore-containing films. See, for example, WO2014/136115 (Reisfeld), which discloses a luminescent solar collector consisting of three glass plates. In the device of the '115 application, a green film is disposed between two adjacent glass plates, and a red film is disposed between two adjacent glass plates. The green layer is a sol-gel layer which includes a silica-polyurethane film containing a highly luminescent europium complex (with phenanthroline or polypiridine) doped with silver nanoparticles. The red film contains Nd³⁺ and Yb³⁺ complexes in a silica-polyurethane matrix doped with copper nanoparticles. This device is designed to split the spectrum of sunlight for enhanced output voltage, similar to a multi junction device. For this design to function as anticipated, each component must be optically isolated to keep waveguided photons from mixing. As such, claim one of the '115 application recites the limitation of “each sheet in said stack being separated from the other by an air-gap”. By contrast, preferred embodiments of the compositions, systems, methodologies and devices disclosed herein do not require any air gaps, and indeed, are devoid of them.

There are several drawbacks that have prevented commercialization of LCs such as those referenced above. First, preparation of large area polymer slabs with the required optical properties is difficult and expensive. The surfaces of the LC must be flat enough to adequately waveguide light over relatively large distances. Any defects formed during manufacturing or due to general use of the LC will cause scattering of light, which allows luminescence to escape the device instead of being concentrated. Second, there is a lack of suitable fluorophores, because both dyes and typical QDs have major limitations. Dyes tend to have narrow absorption bandwidths, poor photostability, and significant self-absorption. QDs tend to contain toxic elements and also suffer from self-absorption. As with scattering due to defects, self-absorption limits LC performance by allowing waveguided photons to be redirected out of the device by absorption and re-emission by the fluorophore and also non-unity quantum yield.

The production of LCs with commercially acceptable performance typically requires (a) highly smooth and robust outer surfaces, and (b) a bright fluorophore with low self-absorbance. In addition, low cost materials and methods, as well as low-toxicity materials, are key enablers of LC technology in most applications, solar or otherwise.

Colloidal semiconductor nanocrystals, also known as quantum dots (QDs), are vanishingly small pieces of semiconductor material that are typically less than 20 nm in diameter. Owing to their small size, these materials have several advantageous properties that include size-tunable photoluminescence (PL) emission over a wide-range of colors, a strong and broadband absorption, and a remarkably high PL efficiency. Changing the size of the QDs is also relatively straightforward due to the solution processing techniques used to synthesize these materials. The ability to tune the QD size, and therefore the absorption/emission spectra, allows flexible fluorescence to be attained across the full color spectrum without the need to modify the material composition.

As QD sizes increase, their absorption onset and photoluminescence (PL) spectra shift to redder wavelengths. Conversely, as QD sizes decrease, their absorption onset and PL spectra shift towards bluer wavelengths. The size tunability of colloidal QDs would be beneficial for LCs, since different colored QDs may be attractive for different applications or different settings. However, most QDs suffer from a large overlap between their absorption and emission spectra, causing significant self-absorption of their PL.

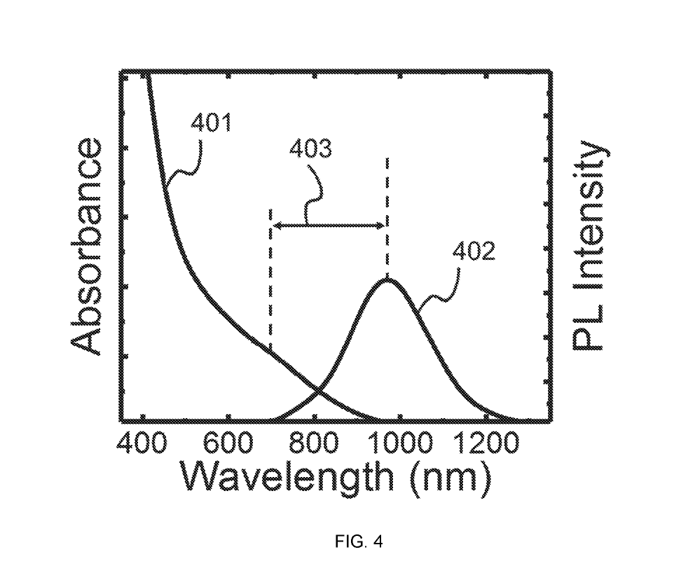

At present, the best performing QDs are composed of CuInSeₓS₂₋ₓ (CISeS), which have the potential to be disruptive in the emerging QD industry owing to their lower manufacturing costs, lower toxicity, and (in some cases) better performance. CuInS₂ (where x=0 in the above formula) outperforms the typical QD material, CdSe, on such critical metrics as toxicity and cost. On other performance metrics, CuInS₂ QDs are favorable as well. For example, CIS QDs have stronger absorption than CdSe QDs. CIS QDs also have a large intrinsic Stokes shift (about 450 meV; see FIG. 4), which limits self-absorption in the material.

Nanocrystal quantum dots of the class of semiconductors, such as CuInS₂, are of growing interest for applications in optoelectronic devices such as solar photovoltaics (see, e.g., PVs, Stolle, C. J.; Harvey, T. B.; Korgel, B. A. Curr. Opin. Chem. Eng. 2013, 2, 160) and light-emitting diodes (see, e.g., Tan, Z.; Zhang, Y.; Xie, C.; Su, H.; Liu, J.; Zhang, C.; Dellas, N.; Mohney, S. E.; Wang, Y.; Wang, J.; Xu, J. Advanced Materials 2011, 23, 3553). These quantum dots exhibit strong optical absorption and stable efficient photoluminescence that can be tuned from the visible to the near-infrared (see, e.g., Zhong, H.; Bai, Z.; Zou, B. J. Phys. Chem. Lett. 2012, 3, 3167) through composition and quantum size effects. In fact, LCs made with specifically engineered quantum dots have recently been shown to offer excellent stability and record conversion efficiency (see Meinardi, F.; McDaniel, H.; Carulli, F.; Colombo, A.; Velizhanin, K. A.; Makarov, N. S.; Simonutti, R.; Klimov, V. I.; Brovelli, S., Highly efficient large-area colourless luminescent solar concentrators using heavy-metal-free quantum dots, Nature Nano., 10, 878, 2015).

### 2. Overview

Laminated glass LCs are needed to solve the primary limitations of existing LCs, especially waveguide quality. Glass can provide a flat and abrasion resistant surface that is effective at waveguiding light due to its higher index of refraction than air. Moreover, the same manufacturing processes that are used to create the laminated glass (for example, safety glass) used in car windshields may be utilized to produce laminated glass LCs. A further advantage is that glass typically has less absorption in the infrared than polymers. This is due to the absence of carbon-hydrogen bonds that have molecular vibration modes which can be excited in the range of 900-1000 nm. Thus, glass can be a better medium for transmission of infrared PL over long distances, making it a superior LC waveguide.

Full spectrum (visible to near-IR, 400-1400 nm) photoluminescent low-toxic fluorophores are needed to embed within the medium between sheets of laminated glass. Typical media that are used in laminated glass are polyvinyl butyral and ethylene-vinyl acetate, but other media, such as silicones and conjugated polymers, may also be used.

Novel laminated glass LCs are disclosed herein which, in a preferred embodiment, contain non-carcinogenic QDs having tunable PL spectra with peaks in the visible (400-650 nm) to near-IR (650-1400 nm). Advantageously, these LCs also have large Stokes shifts, which limits self-absorption of their own photoluminescence and enables the photoluminescence to be guided over large distances of 1 mm to 10 m. In some embodiments, the laminated glass LCs may be coupled to a photovoltaic device for the generation of electricity. In some embodiments, the laminated glass LCs may be partially transparent to, for example, facilitate their use in windows.

Since electricity is one of the biggest expenses for a greenhouse operator or indoor plant grower, there are opportunities for LSCs to be used in agriculture. This LC approach was applied in U.S. 2014/0352762 (Carter et al), entitled “Luminescent Electricity-Generating Window for Plant Growth”, which was filed in 2012, and which notes that “there is a need in the art for luminescent solar collectors which are can produce power with no harm to plant growth.” Another approach to generating electricity for a greenhouse can be found in U.S. 2010/0236164 (Chuang et al), entitled “Photovoltaic Greenhouse Structure,” which was filed in 2009, and which notes that “light which is not absorbed by the thin-film solar cell module freely passes through the thin-film solar cell module and enters the greenhouse inner space.” Similarly, the concept of a laminated glass LC disclosed herein may also be applied in a greenhouse building structure.

### 3. Definitions and Abbreviations

The following explanations of terms and abbreviations are provided to better describe the present disclosure and to guide those of ordinary skill in the art in the practice of the compositions, systems, methodologies and devices described therein.

Luminescent concentrator (LC): A device for converting a spectrum and photon flux of electromagnetic radiation into a new, narrower spectrum with a higher photon flux. LCs operate on the principle of collecting radiation over a large area by absorption, converting it to a new spectrum by PL, and then directing the generated radiation into a relatively small output target by total internal reflection. LCs are typically used for conversion of sunlight into electricity, but can also have uses in lighting, design, and other optical elements.

Photoluminescence (PL): The emission of light (electromagnetic radiation, photons) after the absorption of light. It is one form of luminescence (light emission) and is initiated by photoexcitation (excitation by photons).

Photon flux: The number of photons passing through a unit of area per unit of time, typically measured as counts per second per square meter.

Polymer: A large molecule, or macromolecule, composed of many repeated subunits. Polymers range from familiar synthetic plastics such as polystyrene or poly(methyl methacrylate) (PMMA), to natural biopolymers such as DNA and proteins that are fundamental to biological structure and function. Polymers, both natural and synthetic, are created via polymerization of many small molecules, known as monomers. Exemplary polymers include poly(methyl methacrylate) (PMMA), polystyrene, silicones, epoxy resins, ionoplast, acrylates, vinyl, or even nail polish.

Self-absorption: The percentage of emitted light from a plurality of fluorophores that is absorbed by the same plurality of fluorophores.

Toxic: Denotes a material that can damage living organisms due to the presence of phosphorus or heavy metals such as cadmium, lead, or mercury.

Quantum Dot (QD): A nanoscale particle that exhibits size-dependent electronic and optical properties due to quantum confinement. The quantum dots disclosed herein preferably have at least one dimension less than about 50 nanometers. The disclosed quantum dots may be colloidal quantum dots, i.e., quantum dots that may remain in suspension when dispersed in a liquid medium. Some of the quantum dots which may be utilized in the compositions, systems, methodologies and devices described herein are made from a binary semiconductor material having a formula MX, where M is a metal and X typically is selected from sulfur, selenium, tellurium, nitrogen, phosphorus, arsenic, antimony or mixtures thereof. Exemplary binary quantum dots which may be utilized in the compositions, systems, methodologies and devices described herein include CdS, CdSe, CdTe, PbS, Pb Se, PbTe, ZnS, ZnSe, ZnTe, InP, InAs, Cu₂S, and In₂S₃. Other quantum dots which may be utilized in the compositions, systems, methodologies and devices described herein are ternary, quaternary, and/or alloyed quantum dots including, but not limited to, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdSSe, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, CuIn(Se,S)₂, CuInZn(Se,S)₂, and AgIn(Se,S)₂ quantum dots, although the use of non-toxic quantum dots is preferred. Embodiments of the disclosed quantum dots may be of a single material, or may comprise an inner core and an outer shell (e.g., a thin outer shell/layer formed by any suitable method, such as cation exchange). The quantum dots may further include a plurality of ligands bound to the quantum dot surface.

Quantum Yield (QY): The ratio of the number of emitted photons to the number of absorbed photons for a fluorophore.

Fluorophore: a material which absorbs a first spectrum of light and emits a second spectrum of light. A material that exhibits luminescence or fluorescence.

Stokes shift: the difference in energy between the positions of the absorption shoulder or local absorption maximum and the maximum of the emission spectrum.

Emission spectrum: Those portions of the electromagnetic spectrum over which a fluorophore exhibits PL (in response to excitation by a light source) whose amplitude is at least 1% of the peak PL emission.

### 4. Examples

The following examples are non-limiting, and are merely intended to further illustrate the compositions, systems, methodologies and devices disclosed herein.

### Example 1: Best Mode

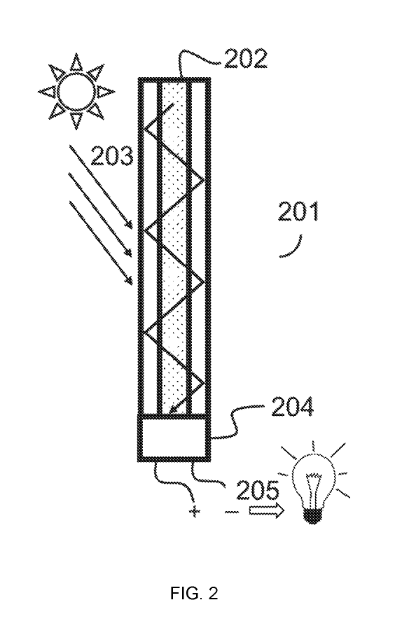

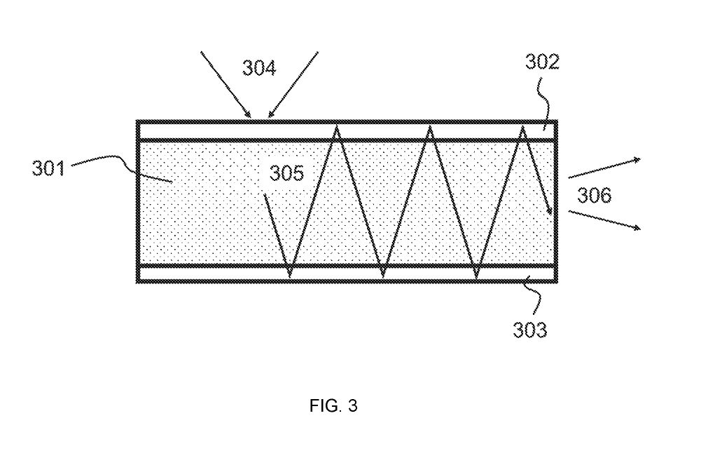

A preferred embodiment of the compositions, systems, methodologies and devices disclosed herein includes fluorophores with low self-absorbance (see FIG. 4) embedded in a medium disposed between two sheets of glass (see FIG. 3), and the coupling of the apparatus to a photovoltaic device for the generation of electricity (see FIG. 2). FIG. 3 depicts the best mode of the invention, wherein a solid medium containing a plurality of fluorophores 301 is disposed in between at least two sheets of glass 302 and 303. When electromagnetic radiation (having an associated spectrum and photon flux) impinges 304 on the LC, emission radiation characterized by a new spectrum is created 305 through the phenomenon of luminescence and is guided in a direction parallel to said sheets of glass. In some embodiments, the fluorophore containing medium absorbs at least 1%, at least 5%, at least 10%, at least 20%, at least 50%, or at least 70% of incident visible light (a subset of 304). In some embodiments, the fluorophore has a quantum yield of at least 20%, at least 40%, at least 60%, at least 80%, at least 90%, or near 100%. In the preferred embodiment, the fluorophore embedded in the medium has a quantum yield of at least 60%. Upon reaching the edge of the LC, the guided luminescence 305 exits the LC with a photon flux 306 that is greater than the incident photon flux 304. In some embodiments, the exiting photons 306 are coupled into a solar cell for the generation of electricity. In other embodiments, the exiting photons 306 are utilized for another purpose besides generation of electricity. In some embodiments, the sheets of glass 302 and 303 are flat, while in other embodiments, they are curved. In the preferred embodiment, the optical transparency of the glass is very high because the sheets of glass 302 and 303 contain less than 1% iron, less than 0.1% iron, or less than 0.01% iron.

The first and second interfaces between the interlayer and glass sheets may be reflective or non-reflective to wavelengths of light selected from the visible, infrared and/or ultraviolet regions of the spectrum. In some embodiments, the solid medium contacts the first and second sheets of glass across first and second non-reflective interfaces. In the preferred embodiment, there is a coating on the surface of the glass facing the light source, and this coating reduces the reflection of that light source. In the preferred embodiment, there is a coating on both outer glass surfaces that selectively reflects the light emitted from the fluorophores in order to keep that light internally reflected. In some embodiments, a low-emissivity coating is applied to one or more glass surfaces to improve the heat transfer properties of the LC. In all embodiments, the solid medium and the first and second sheets of glass are optically coupled to form a waveguide for any of the aforementioned regions of the spectrum. In the preferred embodiment, the medium has an index of refraction that is within 30% of the index of refraction of said glass sheets.

FIG. 4 depicts a typical absorption spectrum 401 and photoluminescence spectrum 402 for exemplary CuInSeₓS₂₋ₓ/ZnS quantum dots. These QDs intentionally do not contain any lead, cadmium, or mercury for environment, health, and safety concerns. This spectrum shows that the absorbance of these optimal plurality of fluorophores is separated in spectrum from the peak of the luminescence 403, which indicates a low self-absorbance and large Stokes shift of greater than 50 meV, greater than 100 meV, greater than 200 meV, or greater than 300 meV. In some embodiments, fluorophores have low self-absorption such that their photoluminescence is absorbed by less than 50% across the integrated spectrum by said fluorophores embedded in said medium over distances of at least 1 mm, at least 1 cm, at least 1 m, or at least 10 m.

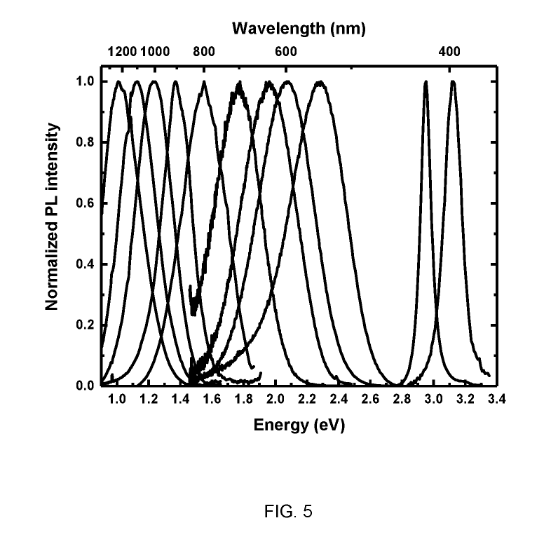

FIG. 5 depicts the wide range of emission spectra that can be achieved with a plurality of fluorophores consisting of quantum dots composed of CuInS₂, CuInSe₂, ZnS, ZnSe, or alloys of the same. The emission peaks can be between 400 nm and 1300 nm. In some embodiments, the QDs have a core/shell structure such as CuInS₂/ZnS QDs having a CuInS₂ core and a ZnS shell. In some embodiments, the QDs have an alloyed semiconductor composition such as CuInSeₓS₂₋ₓ having a combination of CuInSe₂ and CuInS₂.

In the preferred embodiment, the interlayer medium 301 depicted in FIG. 3 is a standard laminated glass interlayer host material such as PVB or ionoplast. The host material may be made by an extrusion process and contains CuInSeₓS₂₋ₓ/ZnS QDs embedded within. Preferably, there are no gaps between the solid medium and the first and second sheets of glass. Also preferably, the solid medium contacts the first and second sheets of glass across first and second non-reflective interfaces. The first and second interfaces may be non-reflective to wavelengths of light selected from the visible, infrared and/or ultraviolet regions of the spectrum. The solid medium and the first and second sheets of glass are preferably optically coupled to form a waveguide for any of the aforementioned regions of the spectrum.

### Example 2: Hot-Pressed Interlayers

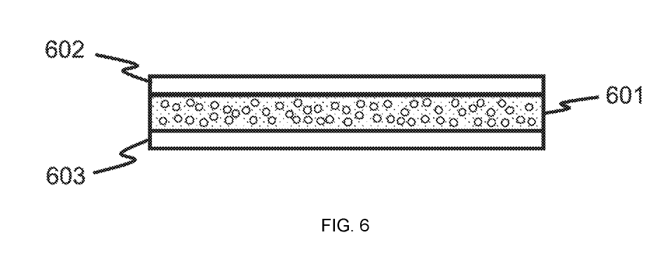

FIG. 6 illustrates another article in accordance with the teachings herein. In this article, CuInS₂/ZnS QDs were mixed into ethylene-vinyl acetate (EVA) sheet 601, and the resulting sheet was hot-pressed between two pieces of glass 602 and 603. The quantum yield of the final EVA-QD composite was measured at 77% when illuminated with 440 nm light, as measured by an integrating sphere. EVA is a good proxy for other commercial interlayers, such as PVB or ionoplast, because it has similar chemical and physical properties. This glass laminate article can be coupled to a photovoltaic device (see FIG. 2) for the generation of electricity.

In some embodiments, quantum dots are first dissolved in a mixture of octanes and hexanes, and cast onto glass or onto the laminating medium between glass sheets. Preferably, the medium is placed between glass sheets after the coating is complete. Heat and pressure is applied to the laminate to adhere the medium to the glass sheets. Alternatively, an adhesion-promoting film can be applied to each interface between the laminating medium and glass. The glass and laminating medium is assembled and cured by heat or UV light depending on the type of adhesion-promoter. Preferably, there are no gaps between the solid medium and the first and second sheets of glass.

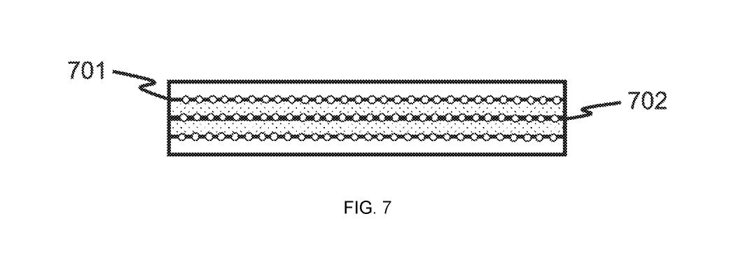

In some embodiments of this example, the compositions, systems, methodologies and devices disclosed herein includes fluorophores with low self-absorbance coated along the interfaces between sheets of glass and one or more interlayer mediums. FIG. 7 depicts the places where QDs can be deposited within an LC, including the interface between glass and an interlayer medium 701 and the interface between two sheets of interlayer medium 702 sandwiched between the outer glass sheets. Preferably, there are no gaps between the quantum dot coating and the solid medium or the quantum dot coating and the glass.

### Example 3: Cured PLMA Interlayer

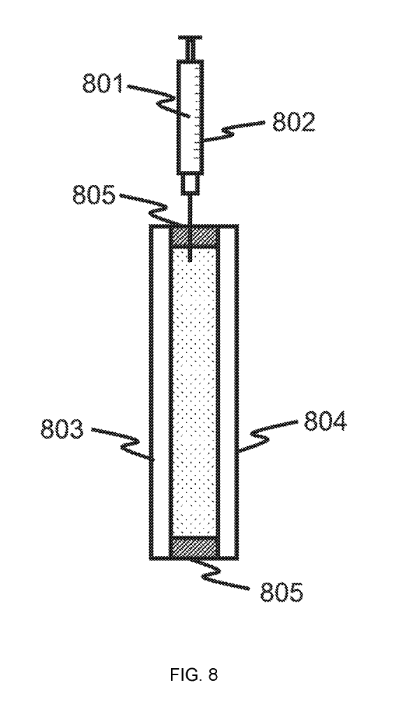

In another test of the invention, QDs emitting at a peak wavelength of 850 nm were embedded in a poly(lauryl methacrylate) (PLMA) co-ethylene glycol sheet, and the sheet was adhered between two vertical pieces of glass. The polymer sheet containing quantum dots was made via a casting process (see FIG. 8). The quantum dots and a UV initiator, such as (2,4,6-Trimethylbenzoyl)diphenylphosphine oxide, were first dissolved in a monomer solution containing 9 parts lauryl methacrylate to 1 part ethylene glycol dimethacrylate. The solution 801 containing monomers, quantum dots and initiator is injected via syringe or other liquid dispenser 802 into the void between two sheets of glass 803 and 804 separated by a gasket 805. The polymer is cured by exposure to UV or heating. Preferably, there are no gaps between the solid medium and the first and second sheets of glass. In some embodiments, the glass sheets 803 and 804 used as the mold also form the LC. In other embodiments, the resulting polymer sheet containing QDs is removed from the mold and fixed between two new pieces of glass to form the LC. Solar cells were placed near the edge of one side of the laminated luminescent solar concentrator for testing. The power output of the device, using no iron glass sheets, was calculated to be greater than 5 W/m² under exposure to sunlight.

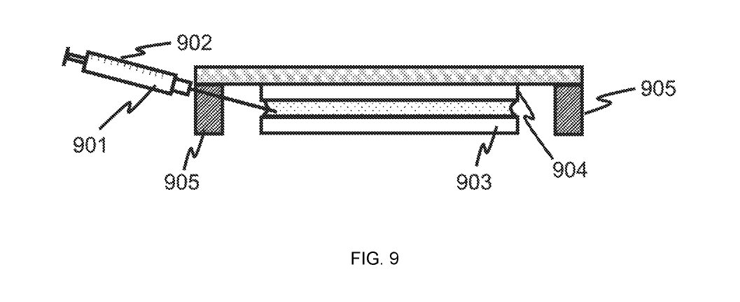

In another implementation of the preferred embodiment, the medium between the two horizontal sheets of glass is a cast polymer such as poly(lauryl methacrylate-co-ethylene glycol dimethacrylate) (see FIG. 9). The quantum dots and a UV initiator, such as (2,4,6-Trimethylbenzoyl)diphenylphosphine Oxide, are first dissolved in a monomer solution containing 9 parts lauryl methacrylate to 1 part ethylene glycol dimethacrylate. Acrylic acid is added at less than 1 w % of the final solution to improve adhesion to the glass. The solution 901 containing monomers, quantum dots and initiator is injected via syringe or other liquid dispenser 902 into the void between two sheets of glass 903 and 904 separated by a gasket. The polymer is then cured by exposure to UV, sunlight, or heat. Preferably, there are no gaps between the solid medium and the first and second sheets of glass. In some embodiments, the gasket is eliminated and the solution 901 is held in place by capillary forces between the glass sheets. In this case, when a gasket is avoided, the glass separation distance can be set by external shims 905.

### Example 4: Nitrocellulose Polymer Interlayer

As a test of one embodiment of the devices disclosed herein, CuInS₂/ZnS QDs were mixed into a nitrocellulose-based polymer and applied between two glass microscope slides. Preferably, there are no gaps between the solid medium and the first and second sheets of glass. Upon curing of the nanocomposite, and under illumination with sunlight, the edges of the glass slide glowed bright yellow, which was the emission color of the QDs that were used. This glass laminate apparatus can be coupled to a photovoltaic (FIG. 2) for the generation of electricity.

### Example 5: Combination with Vehicles and Structures

Glass windows with luminescent tints will enable building-integrated sunlight harvesting and revolutionize urban architecture by turning tinted windows into power sources. With this technology, buildings may eventually realize net zero energy consumption, automated greenhouses will be off-grid, and electric vehicles will charge themselves while sitting parked. As noted above, in a preferred embodiment, the luminescent concentrators disclosed herein are equipped with first and second sheets of glass that have a solid medium containing a plurality of fluorophores disposed between them. Such devices disclosed herein can be used as passive electrical energy supplies on a building or vehicle.

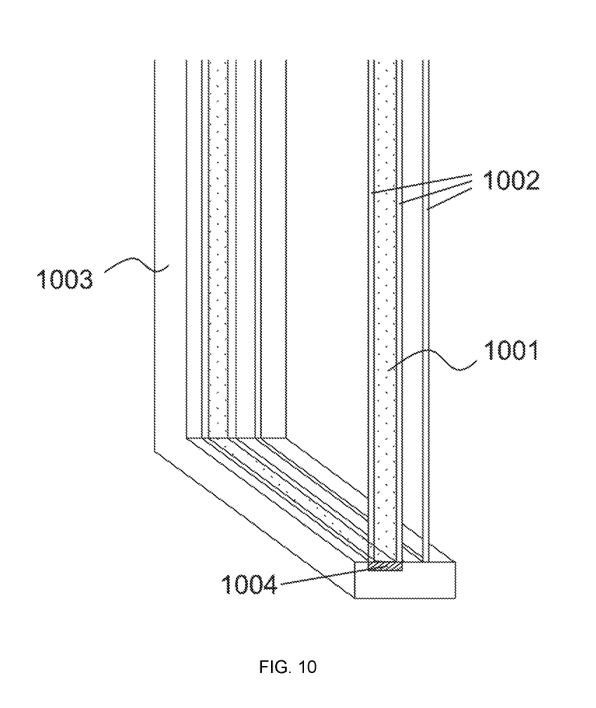

FIG. 10 depicts the laminated glass LC 1001 integrated into an insulated glass unit (IGU) 1002, commonly referred to as a double pane window with three sheets of glass. In some embodiments, the IGU is a triple pane window including a fourth sheet of glass. In some embodiments, the LC-integrated IGU 1002 is combined with a window frame 1003. The LC 1001 need not be part of an IGU to be combined with a window frame 1003, and this is commonly referred to as a single pane window. A solar cell 1004 is integrated into the window frame 1003 or the IGU 1002 or some combination of both, and optically coupled to the LC 1001 for generation of electricity (see FIG. 2).

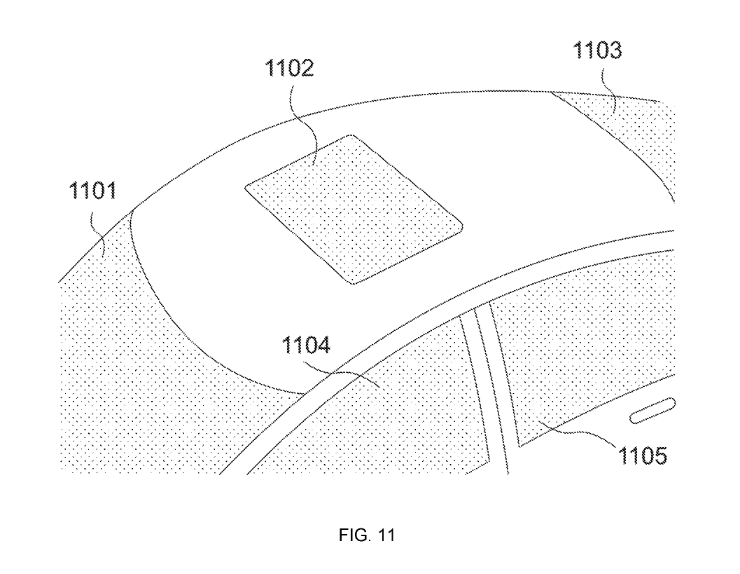

FIG. 11 is a representative schematic of an automobile combined with one or more laminated glass LC windows. The LC can be applied as or integrated into the front windshield 1101, sunroof 1102, rear window 1103, front side window 1104, rear side window 1105, or combinations thereof. Optimally, the LC technology would be combined with an electric vehicle, but gas mileage may be improved for non-electric or hybrid vehicles. In some embodiments, the LC is used to power electrics such as a fan while the vehicle remains parked. In some embodiments, the vehicle is not a car, and is boat, truck, military vehicle, heavy equipment, airplane, helicopter, space vehicle, satellite, or other vehicle.

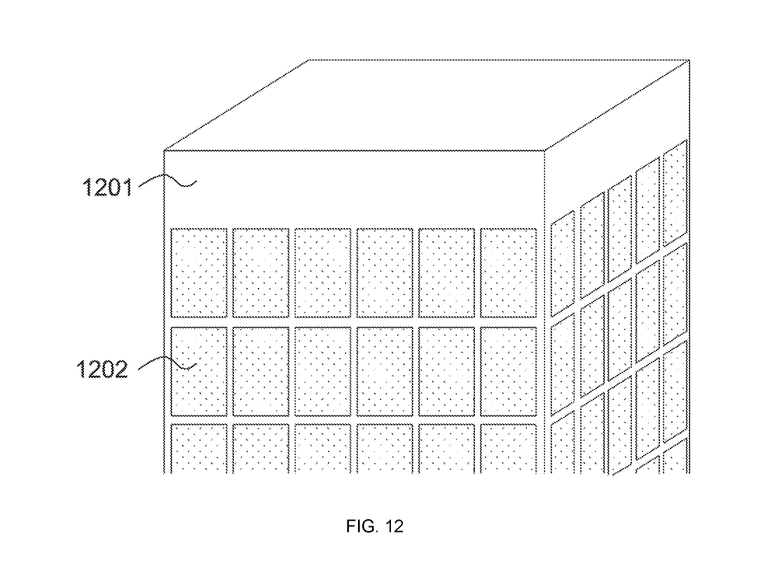

FIG. 12 is a representative schematic of a building structure 1201 combined with one or more laminated glass LC windows 1202. The LC windows 1202 can be applied on one or more sides of the building 1201, or on one or more floors of the building 1202. In some embodiments, the LC windows are flat or rectangular. In other embodiments, the LC windows are curved or have arbitrary shapes. In some embodiments, the building structure contains commercial space, residential space, retail space, or combinations thereof. In some embodiments, the building may be a greenhouse, airport, skyscraper, lunar habitat, non-earth habitat, an undersea habitat, covert military structure, or other building.

### 5. Additional Comments

Various modifications, substitutions, combinations, and ranges of parameters may be made or utilized in the compositions, devices and methodologies described herein without departing from the scope of the present disclosure.

As used herein, “comprising” means “including” and the singular forms “a” or “an” or “the” include plural references unless the context clearly indicates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure relates. Suitable methods and compositions are described herein for the practice or testing of the compositions, systems, methodologies and devices described herein. However, it is to be understood that other methods and materials similar or equivalent to those described herein may be used in the practice or testing of these compositions, systems, methodologies and devices. Consequently, the compositions, systems, methodologies, devices and examples disclosed herein are illustrative only, and are not intended to be limiting. Other features of the disclosure will be apparent to those skilled in the art from the following detailed description and the appended claims.

Unless otherwise indicated, and with respect to all numbers expressing quantities of components, percentages, temperatures, times, and so forth, the scope of the present disclosure includes all instances of such numbers as if modified by the term “about.” Similarly, unless otherwise indicated, and with respect to all non-numerical properties such as colloidal, continuous, crystalline, and so forth, the scope of the present disclosure includes all instances of such non-numerical properties as if modified by the term “substantially”, which term shall mean “to a great extent or degree”. Moreover, unless otherwise indicated implicitly or explicitly, the numerical parameters and/or non-numerical properties set forth are approximations that may depend on the desired properties sought, the limits of detection under standard test conditions or methods, the limitations of the processing methods, and/or the nature of the parameter or property. When directly and explicitly distinguishing embodiments from discussed prior art, the embodiment numbers are not approximates unless the word “about” is recited.

What is claimed is:

1. A luminescent concentrator, comprising:
first and second sheets of glass; and
a luminescent layer disposed between, and in direct contact with, said first and second sheets of glass;
wherein said luminescent layer includes a solid medium containing a plurality of fluorophores.

2. The luminescent concentrator of claim 1, in combination with a photovoltaic device, which converts light into electricity.

3. The luminescent concentrator of claim 1, wherein said luminescent layer absorbs at least 1%, at least 5%, at least 10%, at least 20%, at least 50%, or at least 70% of incident visible light.

4. The luminescent concentrator of claim 1, wherein said fluorophores are quantum dots, and wherein said quantum dots do not contain any element selected from the group consisting of lead, cadmium, and mercury.

5. The luminescent concentrator of claim 1, wherein said fluorophores are quantum dots comprising a material selected from the group consisting of CuInS₂, CuInSe₂, ZnS, ZnSe, and alloys of the same.

6. The luminescent concentrator of claim 1, wherein said medium is selected from the group consisting of ethylene-vinyl acetate, polyvinyl butyral, thermoplastic polyurethane, poly(methyl methacrylate), poly (lauryl methacrylate), acrylate polymer, urethanes, vinyl polymer, cellulose, ionomer, ionoplast, cyclic olefin polymer, epoxies and silicone.

7. The luminescent concentrator of claim 1, wherein said medium contacts said first and second sheets of glass across first and second non-reflective interfaces.

8. The luminescent concentrator of claim 1, wherein said medium has an index of refraction that is within 30% of the index of refraction of said first and second sheets of glass.

9. The luminescent concentrator of claim 1, wherein said first and second sheets of glass contain less than 1% iron, less than 0.1% iron, or less than 0.01% iron.

10. The luminescent concentrator of claim A1, wherein said medium was cured in between said sheets of glass.

11. The luminescent concentrator of claim 1, wherein said medium is coated onto one or both interior sides of the laminated glass prior to assembling the laminated glass.

12. The luminescent concentrator of claim 1, wherein said fluorophore has a quantum yield of at least 20%, at least 40%, at least 60%, at least 80%, at least 90%, or near 100%.

13. The luminescent concentrator of claim 1, wherein said fluorophore has an emission peak between 400 nm and 1300 nm.

14. The luminescent concentrator of claim 1, wherein said fluorophores have a self-absorption of less than 50% of their photoluminescence across the integrated spectrum over distances of at least 1 mm, at least 1 cm, at least 1 m, or at least 10 m.

15. The luminescent concentrator of claim 1, wherein said fluorophores have a Stokes shift of greater than 50 meV, greater than 100 meV, greater than 200 meV, or greater than 300 meV.

16. The luminescent concentrator of claim 1, wherein said medium was made by an extrusion process.

17. The luminescent concentrator of claim 1, wherein said first and second sheets of glass are curved.

18. The luminescent concentrator of claim 1, further comprising at least one coating on at least one of said sheets of glass that selectively reflects said photoluminescence.

19. The luminescent concentrator of claim 1, further comprising at least one coating on at least one of said sheets of glass that reduces the reflection of sunlight.

20. The luminescent concentrator of claim 1, further comprising at least one low-emissivity coating on at least one of said sheets of glass.

21. The luminescent concentrator of claim 1, in combination with an insulated glass unit.

22. The luminescent concentrator of claim 1, in combination with a third sheet of glass.

23. The luminescent concentrator of claim 1, in combination with a window frame.

24. The luminescent concentrator of claim 1, in combination with a vehicle.

25. The luminescent concentrator of claim 1, in combination with a building structure.

26. A method for making a luminescent concentrator, comprising:
providing first and second sheets of glass; and
disposing a luminescent material between, and in direct contact with, said first and second sheets of glass, wherein said luminescent material comprises a medium containing a plurality of fluorophores.

27. The method of claim 26, wherein said luminescent material is a solid medium, and further comprising heating said first and second sheets of glass, thereby forming a laminated glass construct.

28. The method of claim 26, further comprising forming said luminescent material by an extrusion process.

29. The method of claim 26, further comprising using an autoclave to form a laminated glass construct.

30. The method of claim 26, wherein said luminescent material is curable, wherein the luminescent material is disposed between, and in direct contact with, said first and second sheets of glass while it is in an uncured state, and further comprising:
curing the uncured luminescent material.

31. A method for making a luminescent concentrator, comprising:
providing first and second sheets of glass;
coating a first surface of the first sheet of glass with a luminescent material, thereby forming a first coated surface, wherein said luminescent material comprises a medium containing a plurality of fluorophores; and
assembling the first and second sheets of glass into a construct such that the first coated surface is facing the second sheet of glass.

32. The method of claim 31, further comprising:
coating a first surface of the second sheet of glass with the luminescent material, thereby forming a second coated surface; and
assembling the first and second sheets of glass into a construct such that the first and second coated surfaces are facing each other.
